(19) United States
(12) Patent Application Publication
(10) Pub. No.: US 2021/0341610 A1
(43) Pub. Date: Nov. 4, 2021

(54) RANGING DEVICE

(71) Applicant: SZ DJI TECHNOLOGY CO., LTD., Shenzhen (CN)

(72) Inventors: Shuai DONG, Shenzhen (CN); Xiaoping HONG, Shenzhen (CN); Huai HUANG, Shenzhen (CN)

(21) Appl. No.: 17/369,549

(22) Filed: Jul. 7, 2021

Related U.S. Application Data
(63) Continuation of application No. PCT/CN2019/070638, filed on Jan. 7, 2019.

(51) Int. Cl. G01S 17/18; G01S 7/484; G01S 7/486; H01L 31/107; G01S 7/481

(52) U.S. Cl. CPC G01S 17/18; G01S 7/484; G01S 7/4817; H01L 31/107; G01S 7/486

(57) ABSTRACT

A ranging device includes a light source, a transceiver, a detector, and a light path changing element. The light source is configured to emit a light pulse. The transceiver is configured to collimate the light pulse and converge at least part of reflected light of the light pulse reflected by a detection object. The detector is configured to receive and convert the at least part of the reflected light into an electrical signal for measuring a distance between the detection object and the ranging device. The light path changing element is configured to combine emission light path and reception light path. The light path changing element includes an area configured to transmit or reflect part of the light pulse, and a reception solid angle of the area with respect to the light pulse is 20%-40% of a reception solid angle of the detector with respect to the reflected light.

### CROSS-REFERENCE TO RELATED APPLICATION

This application is a continuation of International Application No. PCT/CN2019/070638, filed Jan. 7, 2019, the entire content of which is incorporated herein by reference.

### TECHNICAL FIELD

The present disclosure relates to the technical field of LIDAR and, more particularly, to a ranging device.

### BACKGROUND

A LIDAR is a radar system that emits a laser beam to detect features such as position and speed of a target. A photosensitive sensor of the LIDAR can convert an obtained light pulse signal into an electric signal, and time information corresponding to the electric signal is obtained based on a comparator, thereby distance information between the LIDAR and the target is obtained.

Current radar ranging or detection systems generally use coherent detection or direct signal detection. The coherent detection generally uses laser polarization characteristics, and uses an interference of emitted light and reflected light for detection. This solution needs to ensure polarization characteristics of the reflected light and requires more polarization units. Light sources and signals require modulation and demodulation, etc., which are costly and suitable for weak signal long-range detection. The direct detection mostly uses a system structure with separate transmission and reception shafts, and this solution requires more lens structures. In a ranging device, a ranging method mostly uses a triangulation method, which has many lenses and high optical cost, and is more suitable for close-range high-precision detection (˜um level). For a transceiver coaxial structure, a phase method or a pulse method is mostly used.

In the ranging device, a light source generally uses an edge-emitting laser (EEL), and an avalanche diode (APD) is used as a receiving element, where both EEL and APD are used as key components to realize laser beam generation and detection. APD is generally circular or square, while an echo spot is elliptical and approximately rectangular if the EEL laser is used. Circular photosensitive surface of the APD and the echo spot are difficult to match well, so that signal-to-noise ratio is low and ranging range is reduced.

Therefore, as described above, there are a variety of problems that need to be urgently solved in the existing ranging device.

### SUMMARY

In accordance with the disclosure, there is provided a ranging device including a light source, a transceiver, a detector, and a light path changing element. The light source is configured to emit a light pulse. The transceiver is configured to collimate the light pulse and converge at least part of reflected light of the light pulse reflected by a detection object. The detector is configured to receive and convert the at least part of the reflected light into an electrical signal for measuring a distance between the detection object and the ranging device. The light path changing element is configured to combine emission light path and reception light path. The light path changing element includes an area configured to transmit or reflect part of the light pulse, and a reception solid angle of the area with respect to the light pulse is 20%-40% of a reception solid angle of the detector with respect to the reflected light.

### BRIEF DESCRIPTION OF THE DRAWINGS

In order to explain the embodiments of the present disclosure more clearly, reference is made to the accompanying drawings, which are used in the description of the embodiments or the existing technology. Obviously, the drawings in the following description are some embodiments of the present disclosure, and other drawings can be obtained from these drawings without any inventive effort for those of ordinary skill in the art.

FIG. 1 is a schematic diagram of a LIDAR transceiver coaxial system in a ranging device according to an embodiment of the present disclosure.

FIG. 2 is a schematic diagram showing light emission of an edge-emitting laser diode in a ranging device according to an embodiment of the present disclosure.

FIGS. 3A-3E are schematic structural diagrams of a light path changing element in a ranging device according to an embodiment of the present disclosure.

FIG. 4 is a schematic diagram of a LIDAR transceiver coaxial system in a ranging device according to another embodiment of the present disclosure.

FIG. 5 is a schematic diagram of a LIDAR transceiver coaxial system in a ranging device according to another embodiment of the present disclosure.

FIG. 6 is a schematic diagram of a LIDAR transceiver coaxial system in a ranging device according to another embodiment of the present disclosure.

FIG. 7 is a schematic diagram of a LIDAR transceiver coaxial system in a ranging device according to another embodiment of the present disclosure.

FIG. 8 is a schematic diagram showing an embodiment in which a ranging device employs a coaxial optical path according to an embodiment of the present disclosure.

FIG. 9 shows a schematic structural diagram of an EEL in a ranging device according to an embodiment of the present disclosure.

FIG. 10 shows a cross-sectional view of the EEL in FIG. 9 along B-B direction.

FIG. 11 is a schematic diagram showing a shape of an APD photosensitive surface in a ranging device according to an embodiment of the present disclosure.

FIG. 12 is a schematic diagram showing a shape of an APD photosensitive surface in a ranging device according to another embodiment of the present disclosure.

FIG. 13 is a schematic diagram showing a relationship between an APD photosensitive surface and an echo spot in a ranging device according to another embodiment of the present disclosure.

FIG. 14 is a schematic diagram showing a shape of an APD array photosensitive surface in a ranging device according to an embodiment of the present disclosure.

FIG. 15 is a schematic diagram showing a shape of an APD array photosensitive surface in a ranging device according to another embodiment of the present disclosure.

### DETAILED DESCRIPTION OF THE EMBODIMENTS

The technical solutions in the embodiments of the present disclosure will be described in detail with reference to the accompanying drawings. Obviously, the described embodiments are only some of rather than all the embodiments of the present disclosure. Based on the described embodiments, all other embodiments obtained by those of ordinary skill in the art without inventive effort shall fall within the scope of the present disclosure.

Current radar ranging or detection systems generally use coherent detection or direct signal detection. But each has various drawbacks, such as more polarization units are required, light sources and signals require modulation and demodulation, etc., which are costly and suitable for weak signal long-range detection; or more lens structures are required; or optical cost is high, etc.

In a ranging device, a light source generally uses an edge-emitting laser (EEL), and an avalanche diode (APD) is used as a receiving element. Due to a flat and narrow light emission area, such as 75 um×10 um or 150 um×10 um, spot size is also rectangular after collimation by an optical system. Correspondingly, after a laser is reflected on an object and received by a LIDAR, a spot formed on a focal plane is also rectangular.

In order to detect an echo signal with the APD, it is often necessary to have a photosensitive surface size of the APD larger than the spot size, but it is not that larger is better. When the photosensitive surface size of the APD increases, an area larger than the photosensitive surface will receive more stray light, etc., and noise is formed. When the photosensitive surface size increases, an electrical noise caused by surface leakage current, etc. will also increase. An increase of noise will deteriorate noise characteristics of the system and reduce ranging characteristics of the system. When the photosensitive surface size of the APD increases, cost will increase. The photosensitive surface of the APD is generally set to be circular or square, and it is impossible to easily adjust circular diameter to make the photosensitive surface match well with an echo spot.

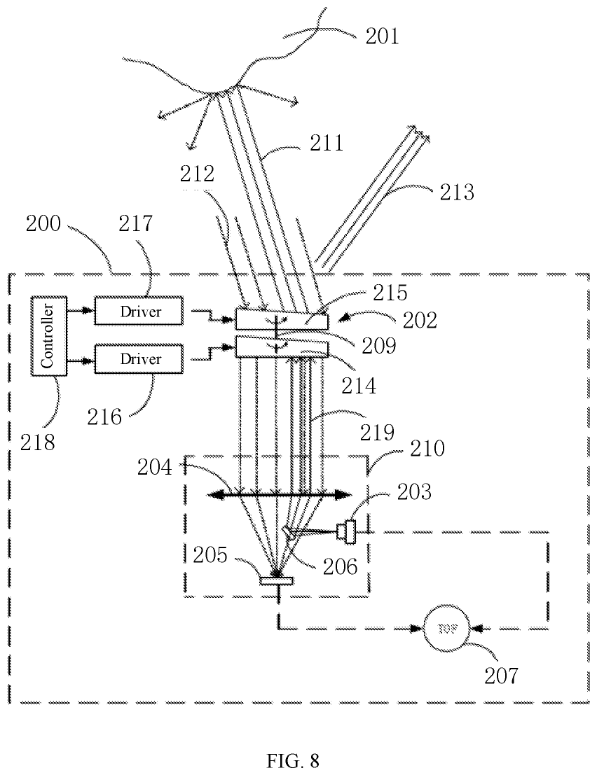

In order to solve at least one of the various problems described above, the present disclosure provides a ranging device. Hereinafter, an overall structure of the ranging device in the embodiments of the present disclosure will be described first with reference to FIG. 8, and then transceiver coaxial systems in the ranging device will be described in detail.

Referring to FIG. 8 first, FIG. 8 shows a schematic diagram of a ranging device using a coaxial light path according to an embodiment of the present disclosure.

A ranging device 200 includes a ranging module 210, which includes a light source 203 (which may include a transmission circuit), a collimation element 204, a detector 205 (which may include the reception circuit, the sampling circuit, and the arithmetic circuit described above), and a light path changing element 206. The ranging module 210 is configured to emit the light beam, receive the reflected light, and convert the reflected light into the electrical signal. The light source 203 can be configured to emit the light sequence. In some embodiments, the light source 203 may emit the laser pulse sequence. For example, a laser beam emitted by the light source 203 is a narrow-bandwidth beam with a wavelength outside visible light range. The collimation element 204 is arranged on the transmission light path of the light source, and is configured to collimate the light beam emitted from the light source 203 and collimate the light beam emitted from the light source 203 into parallel light output to the scanning module. The collimation element is also configured to converge at least part of the reflected light reflected by a detection object (also referred to as a “target object”). The collimation element 204 may be a collimation lens or another element capable of collimating the light beam.

In the embodiments shown in FIG. 8, the transmission light path and the reception light path within the ranging device are merged before the collimation element 204 by the light path changing element 206, so that the transmission light path and the reception light path can share the same collimation element, which makes the light path more compact. In some other implementations, the light source 203 and the detector 205 may respectively use their own collimation elements, and the light path changing element 206 is arranged on the light path behind the collimation element.

In the embodiment shown in FIG. 8, since beam aperture of the light beam emitted by the light source 203 is small, and beam aperture of the reflected light received by the ranging device is large, the light path changing element can use a small-area reflector to merge the transmission light path and the reception light path. In some other implementations, the light path changing element may also use a reflector with a through hole, where the through hole is used to transmit emitted light of the light source 203 and the reflector is used to reflect the reflected light to the detector 205, which can reduce block of the reflected light from a support of a small reflector in case of using the small reflector.

In the embodiments shown in FIG. 8, the light path changing element is deviated from an optical axis of the collimation element 204. In some other implementations, the light path changing element may also be located on the optical axis of the collimation element 204.

The ranging device 200 also includes a scanning module 202 arranged on the transmission light path of the ranging module 210. The scanning module 202 is configured to change transmission direction of a collimated light beam 219 emitted by the collimation element 204 and project it to external environment. The reflected light is projected to the collimation element 204, and is converged on the detector 205 through the collimation element 204.

In some embodiments, the scanning module 202 may include at least an optical element for changing propagation path of the light beam, and the optical element may change the propagation path of the light beam by reflecting, refracting, diffracting, etc. For example, the scanning module 202 includes a lens, a reflector, a prism, a galvanometer, a grating, a liquid crystal, an optical phased array, or any combination of the above. In some embodiments, at least some of the optical elements are movable, for example, the at least some of the optical elements are driven to move by a drive module, and the movable optical element can reflect, refract or diffract the light beam to different directions at different times. In some embodiments, the multiple optical elements of the scanning module 202 can rotate or vibrate around a common rotation axis 209, and each rotating or vibrating optical element is configured to continuously change the propagation direction of an incident light beam. In some embodiments, the multiple optical elements of the scanning module 202 may rotate at different rotation speeds or vibrate at different speeds. In some other embodiments, the at least some of the optical elements of the scanning module 202 may rotate at substantially the same rotation speed. In some embodiments, the multiple optical elements of the scanning module may also rotate around different axes. In some embodiments, the multiple optical elements of the scanning module may also rotate in the same direction or in different directions; or vibrate in the same direction or in different directions, which is not limited herein.

In some embodiments, the scanning module 202 includes a first optical element 214 and a driver 216 connected to the first optical element 214. The driver 216 is configured to drive the first optical element 214 to rotate around the rotation axis 209, such that the first optical element 214 changes the direction of the collimated light beam 219, and the first optical element 214 projects the collimated light beam 219 to different directions. In some embodiments, angle between the direction of the collimated light beam 219 changed by the first optical element and the rotation axis 209 varies with the rotation of the first optical element 214. In some embodiments, the first optical element 214 includes a pair of opposing non-parallel surfaces through which the collimated light beam 219 passes. In some embodiments, the first optical element 214 includes a prism that varies in thickness along at least a radial direction. In some embodiments, the first optical element 214 includes a wedge angle prism that refracts the collimated light beam 219.

In some embodiments, the scanning module 202 also includes a second optical element 215 that rotates around the rotation axis 209, and the rotation speed of the second optical element 215 is different from the rotation speed of the first optical element 214. The second optical element 215 is configured to change the direction of the light beam projected by the first optical element 214. In some embodiments, the second optical element 215 is connected to another driver 217 that drives the second optical element 215 to rotate. The first optical element 214 and the second optical element 215 can be driven by the same or different drivers, so that the rotation speed and/or rotation direction of the first optical element 214 and the second optical element 215 are different, thereby projecting the collimated light beam 219 to different directions in outside space, and a larger space can be scanned. In some embodiments, a controller 218 controls the drivers 216 and 217 to drive the first optical element 214 and the second optical element 215, respectively. The rotation speeds of the first optical element 214 and the second optical element 215 may be determined according to area and pattern expected to be scanned in actual applications. The drivers 216 and 217 may include motors or other drivers.

In some embodiments, the second optical element 215 includes a pair of opposing non-parallel surfaces through which the light beam passes. In some embodiments, the second optical element 215 includes a prism that varies in thickness along at least a radial direction. In some embodiments, the second optical element 215 includes a wedge angle prism.

In some embodiments, the scanning module 202 also includes a third optical element (not shown) and a driver for driving the third optical element to move. For example, the third optical element includes a pair of opposing non-parallel surfaces through which the light beam passes. In some embodiments, the third optical element includes a prism that varies in thickness along at least a radial direction. In some embodiments, the third optical element includes a wedge angle prism. At least two of the first, second, and third optical elements rotate at different rotation speeds and/or rotation directions.

Each optical element in the scanning module 202 can rotate to project light to different directions, such as directions of projected light 211 and projected light 213, so that a space around the ranging device 200 is scanned. When the projected light 211 projected by the scanning module 202 hits a detection object 201, part of the light is reflected by the detection object 201 to the ranging device 200 in a direction opposite to the projected light 211. Reflected light 212 reflected by the detection object 201 is incident to the collimation element 204 after passing through the scanning module 202.

The detector 205 and the light source 203 are arranged on the same side of the collimation element 204, and the detector 205 is configured to convert at least part of the reflected light passing through the collimation element 204 into an electrical signal.

In some embodiments, each optical element is plated with an anti-reflection coating. For example, thickness of the anti-reflection coating is equal to or close to wavelength of the light beam emitted by the light source 203, which can increase intensity of the transmitted light beam.

In some embodiments, a filter layer is plated on an element surface located on beam propagation path in the ranging device, or a filter is provided on the beam propagation path, which is configured to at least transmit wavelength band of the beam emitted by the light source and reflect other wavelength bands, so as to reduce noise caused by ambient light to receiver.

In some embodiments, the light source 203 may include a laser diode, and emit a nanosecond level laser pulse through the laser diode. Further, laser pulse receiving time can be determined, for example, by detecting rising edge time and/or falling edge time of an electrical signal pulse. As such, the ranging device 200 can calculate time of flight (TOF) using pulse receiving time information and pulse sending time information, so as to determine the distance between the detection object 201 and the ranging device 200.

The distance and orientation detected by the ranging device 200 can be used for remote sensing, obstacle avoidance, surveying and mapping, modeling, navigation, etc. In some embodiments, the ranging device according to the embodiments of the present disclosure can be applied to a mobile platform, and the ranging device can be mounted at a platform body of the mobile platform. The mobile platform with the ranging device can measure external environment, for example, to measure distance between the mobile platform and an obstacle for obstacle avoidance and other purposes, and to perform two-dimensional or three-dimensional surveying and mapping of the external environment. In some embodiments, the mobile platform includes at least one of an unmanned aerial vehicle, a car, a remote control vehicle, a robot, a camera, or a boat. When the ranging device is applied to an unmanned aerial vehicle, the platform body is a vehicle body of the unmanned aerial vehicle. When the ranging device is applied to a car, the platform body is a vehicle body of the car. The car can be a self-driving car or a semi-self-driving car, which is not limited here. When the ranging device is applied to a remote control vehicle, the platform body is a vehicle body of the remote control vehicle. When the ranging device is applied to a robot, the platform body is the robot. When the ranging device is applied to a camera, the platform body is the camera itself.

The overall structure and working principle of the ranging device in the above embodiments are explained and described. A coaxial optical path from a light source to a detector in the ranging device of the embodiments of the present disclosure will be described in detail below with reference to the accompanying drawings.

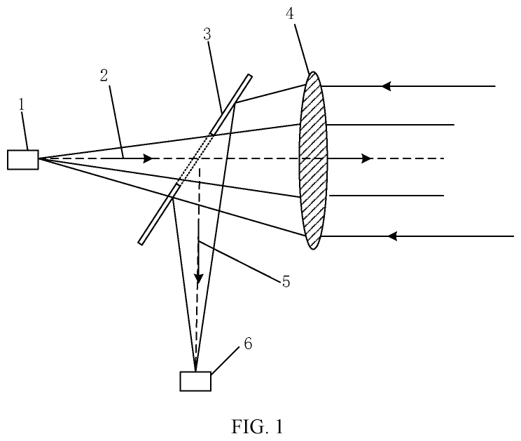

Referring to FIG. 1 first, in another embodiment of the present disclosure, the ranging device includes a light source 1, a transceiver 4, a detector 6, and a light path changing element 3. The light source 1 is configured to emit a light pulse. The transceiver 4 is configured to collimate the light pulse 2 emitted by the light source, and converge at least part of the reflected light of the light pulse reflected by the reflected object. The detector 6 is arranged on the same side of the transceiver as the light source, and is configured to receive at least part of the reflected light 5 converged by the transceiver, and convert the received reflected light into an electrical signal for measuring distance between the detection object and the ranging device. The light path changing element 3 is arranged on the same side of the transceiver as the light source and the detector, and is configured to combine emission light path of the light pulse and reception light path of the detector. The light path changing element includes a first area for transmitting or reflecting part of the light pulse from the light source to the transceiver, and a reception solid angle of the first area with respect to the light pulse is 20%-40% of a reception solid angle of the detector with respect to the reflected light.

It should be noted that, for the light source and the detector, reference can be made to the related description in the above-mentioned embodiments of the present disclosure. Below is the detailed description of the transceiver 4 and the light path changing element 3 as an emphasis.

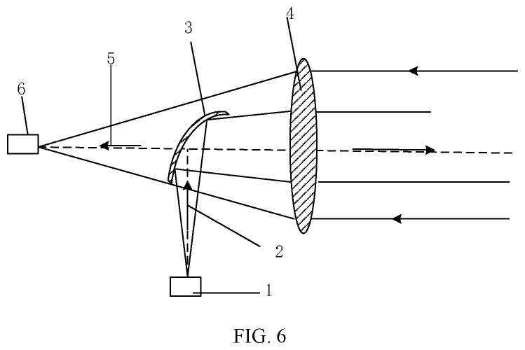

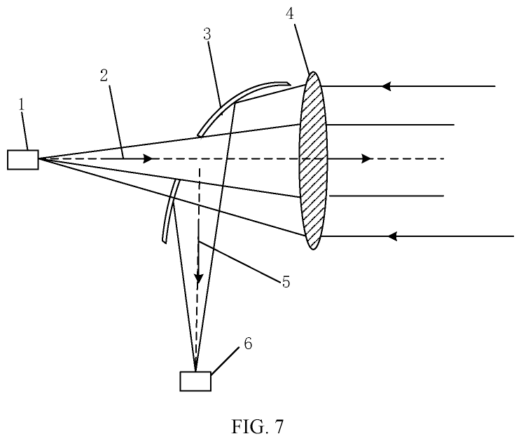

In some embodiments of the present disclosure, the light path changing element 3 can either be an optical element with a flat surface, as shown in FIG. 1, or an optical element with a curved surface, as shown in FIGS. 6 and 7, which is not limited.

For example, the light path changing element 3 uses a reflector with a concave surface, which can shorten receiving focal length of the detector, so that the whole system is more compact in receiving direction. Also, application of a concave reflector makes reception and transmission lens systems different, so that FOV of the reception system is larger, and an received optical signal is stronger.

Regardless of whether a flat or curved optical element is used for the light path changing element 3, it is required that the reception solid angle of the first area with respect to the light pulse is 20%-40% of the reception solid angle of the detector with respect to the reflected light. With this configuration, not only an effective area of the light path changing element 3 for transmission or reflection of emitted light pulse is considered, but also an area of the light path changing element 3 for reflection or transmission of the reflected light is considered. A ratio of the two is comprehensively considered, and a signal ratio of the light pulse transmitted or reflected to the transceiver on the light path changing element 3 to the light pulse of the reflected light reflected by the detection object received by the detector after passing through the light path changing element 3 can be optimized through this configuration, so that the detection device can achieve the longest detection distance.

A solid angle refers to, when the light pulse use apex of a vertebral body as a spherical center to make a spherical surface, a ratio of an area of the vertebral body intercepted on the spherical surface to the square of spherical radius, and the unit is steradian. When the angle is not large, the solid angle can be approximated as a ratio of a plane area of the vertebral body to the square of side of the vertebral body. In some embodiments, the reception solid angle of the first area with respect to the light pulse is a ratio of a projected area of the first area on a plane perpendicular to the optical axis of the light pulse to the square of the distance between the plane and the light source. Without special instructions, for the solid angles mentioned below, reference can be made to this explanation and description.

The solid angle is also related to a numerical aperture of the transceiver. In some embodiments, the numerical aperture of the transceiver is 0.15-0.5.

The light path changing element 3 may also include a second area, where the first area is configured to transmit part of the light pulse from the light source to the transceiver, and the second area is configured to reflect part of the reflected light converged by the transceiver to the detector, as shown in FIG. 1; or, the light path changing element 3 may also include a second area, where the first area is configured to reflect part of the light pulse from the light source to the transceiver, and the second area is configured to transmit part of the reflected light converged by the transceiver to the detector.

In some embodiments, the center of the first area coincides with the optical axis of the emitted light pulse of the light source, so as to ensure that enough light pulse can be transmitted or reflected by the light path changing element 3.

In some other embodiments, the center of the first area deviates from the optical axis of the transceiver. For example, the light path changing element 3 is obliquely arranged, and an included angle between the light path changing element 3 and the optical axis of the transceiver is approximately 45°.

In some embodiments of the present disclosure, the light path changing element 3 includes the first area and the second area, where the first area is configured to transmit part of the light pulse from the light source to the transceiver, and the second area is configured to reflect part of the reflected light converged by the transceiver to the detector. Specifically, the light pulse 2 emitted by the light source 1 pass through the light path changing element 3 and reach the transceiver 4 (e.g., a collimation receiving lens), then hit the detection object after being collimated. The reflected light 5 reflected by the detection object is received by the collimation receiving lens, and reaches the detector 6 through a semi-reflective lens. Received signal is further processed with some amplification, filtering, and algorithm, so that detection of target distance and angle is completed.

In some embodiments, the light source 1 and the detector 6 are respectively located on backward focal points of the transceiver (e.g., a collimation receiving lens). The collimation receiving lens is a special cemented lens group or an aspheric lens or a gradient refractive index lens, and severs as a collimation lens for emitted laser and also as a receiving lens for the reflected light, which has the advantages of small aberration, low cost, and easy processing.

The light path changing element 3 is located within a backward focal length of the collimation receiving lens, which has a transmission effect on the emitted laser and a reflection effect on the reflected light. Direction of sending and receiving signals can be separated by using different solid angles of the lens.

Specifically, the transceiver 4 may include at least one of a lens group, an aspheric lens, or a gradient refractive index lens. The lens group may include a combination of a plurality of concave lenses and a plurality of convex lenses, where the number and combination mode are not limited and can be set according to actual needs. In some embodiments, the transceiver 4 uses a convex lens.

The specific shape of the light path changing element 3 is not limited, and can be implemented to the embodiments as long as the transmitting laser can be transmitted and the received signal can be reflected.

In some embodiments, shape of the projection of the first area on a plane perpendicular to the optical axis of the light pulse matches shape of the light spot of the light pulse formed on the plane, so that the light pulse is projected on the first area as much as possible to increase a measurement range. For example, the shape of the projection of the first area on the plane perpendicular to the optical axis of the light pulse is circular, elliptical, trapezoidal, or rectangular that matches the shape of the light spot of the light pulse formed on the plane, but is not limited to the shapes described above, and another feasible shape can also be used.

In some embodiments, the projected area of the first area on the plane perpendicular to the optical axis of the light pulse is smaller than a light spot area of the light pulse formed on the plane, so that the first area is effectively and sufficiently used.

In some embodiments, the shape of the first area matches the shape of light emission surface of the light source, and the shape of the light emission surface of the light source is the same as the shape of the light spot of the light pulse formed on the plane perpendicular to the optical axis. A transmission window of the light path changing element 3, that is, an angular aperture and shape opened to the light source 1 or the detector 6, match the light spot of the selected light source. For example, the light source is a long strip light spot, an equivalent transmission window of the light path changing element 3 is a long strip corresponding to long and short directions; if the light source is a circular light spot, the equivalent transmission window of the light path changing element 3 is also matched to be circular; if the light source is an elliptical light spot, the equivalent transmission window of the light path changing element 3 is also matched to be elliptical corresponding to long and short directions; if the light source is a trapezoidal light spot, the equivalent transmission window of the light path changing element 3 is also matched to be trapezoidal corresponding to long and short directions.

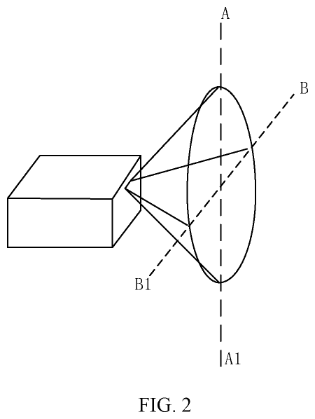

In some embodiments, the light source uses an edge-emitting laser diode, and divergence angles of radiated light field in fast axis and slow axis directions are different, as shown in FIG. 2, where A-A1 is the fast axis direction, and B-B1 is the slow axis direction. In the fast and slow axis directions, half-maximum width of the divergence angle is 15°-30° and 6°-15° respectively. Its radiation light spot is elliptical, so a reflector opening is set to be elliptical or rectangular matched with the light spot, so that better performance can be obtained. Correspondingly, aperture of the first area in the fast axis direction of the laser diode is larger than aperture in the slow axis direction of the laser diode, so that the first area matches the light spot of the edge-emitting laser diode.

In some embodiments, the first area includes a lower end and an upper end located at two sides of the optical axis, where the lower end is closer to the light source than the upper end, as shown in FIG. 1, and an aperture of the upper end is larger than an aperture of the lower end in a direction parallel to the optical axis of the light pulse. For example, an actual area and shape of the first area (transmission window) of the light path changing element 3 are related to a tilt angle, and are specifically determined by overlapping and interception of an effective solid angle emitted by the light source along the optical axis and the tilted light path changing element 3. Because of this tilt, shape of the equivalent transmission window of the reflector is similar to a trapezoid, with a wide upper part and a narrow bottom part. Also, the larger the tilt angle, the larger an upper and lower width ratio of the trapezoid.

In some embodiments, the projected area of the first area on the plane perpendicular to the optical axis of the light pulse is 20%-40% of a projected area of the second area on the plane. The light path changing element is configured to emit light pulse with 60%-85% energy of a total energy of the light pulse emitted by the light source to the transceiver. An energy of the reflected light received by the detector accounts for more than 60% of an energy of the reflected light received by the light path changing element. In order to ensure an effective area ratio of the transmission and reflection of the light path changing element 3, a ratio of received signal lost by the transmission window through the lens is considered, while an intensity distribution and actual emission ratio of laser source are considered at the same time. By reasonably setting size of the transmission window, emitted laser energy is moderate, and the emitted laser energy and target reflection signal both reach a certain intensity and energy, thereby increasing the measurement range, so as to avoid the problem that the actual area of the equivalent first area (transmission window) of the light path changing element 3 is too large, the emitted laser energy is higher, but the received signal is reduced due to energy loss of the equivalent transmission window that causes the energy loss.

The light path changing element 3 is arranged within the backward focal length of the collimation receiving lens, and the closer to the lens, the better (processing tolerance and assembly error sensitivity will be reduced).

In some embodiments of the present disclosure, the detector is arranged on a focal plane of the transceiver, and the light source is arranged on one side of the optical axis of the transceiver; or the light source is arranged on the focal plane of the transceiver, and the detector is arranged on one side of the optical axis of the transceiver.

Further, the light path changing element is arranged between the transceiver and the light source, as shown in FIGS. 1, 4, and 7, which allows the light pulse emitted by the light source to be transmitted, and allows the reflected light passing through the transceiver to be reflected to the detector. In this arrangement, an effective aperture of the transceiver is smaller than an effective aperture of the light path changing element.

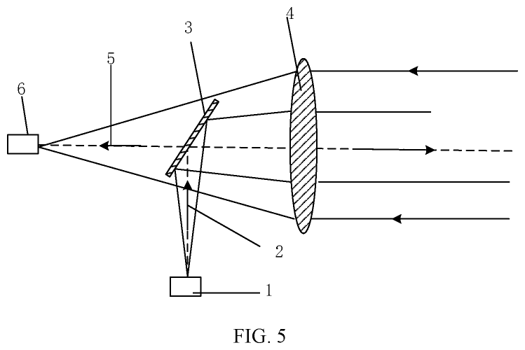

Or as shown in FIGS. 5 and 6, the light path changing element is arranged on the same side of the transceiver and the light source, which allows the light pulse emitted by the light source to be reflected, and allows the reflected light passing through the transceiver to be emitted to the detector. Also, the effective aperture of the transceiver is larger than the effective aperture of the light path changing element. The basic structure and principle are the same as the examples shown in FIGS. 1, 4, and 7, except that the positions of the detector and the light source are switched, and volume of the light path changing element 3 becomes smaller. The light path changing element reflects the emitted light pulse and transmits reflected light signal, and the basic characteristics are unchanged.

As described above, in some embodiments of the present disclosure, the light path changing element 3 can either be an optical element with a flat surface, as shown in FIG. 1, or an optical element with a curved surface, as shown in FIGS. 6 and 7.

The coaxial optical path is described through the above-mentioned embodiments. The specific structure of the light path changing element 3 and embodiments of using other types of optical elements are described below. It should be noted that the following embodiments can all be implemented to the above-mentioned embodiments as long as they are not mutually inconsistent with each other.

In some embodiments, the light path changing element 3 includes the first area and the second area. Below is the description of an example where the first area is a transmission window and the second area is a reflection window. The first area includes a light-transmitting substrate, and a surface of the first area facing and/or facing away from the light source is coated with an antireflection film; or, a surface of the light path changing element facing the light source is coated with the antireflection film; or, the first area is provided with a polarizing film, and polarization direction of the polarizing film is the same as polarization direction of the emitted light pulse. Specifically, implementations of the solution described above are listed as follows.

First, the light path changing element 3 is set as a reflector with opening.

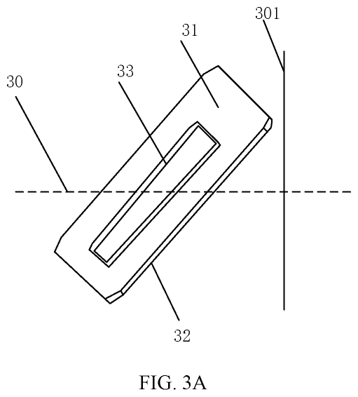

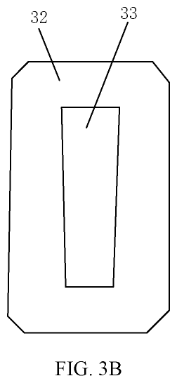

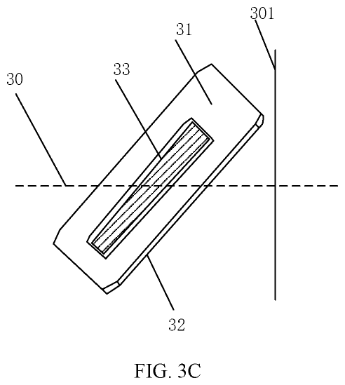

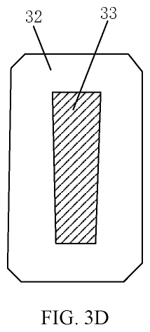

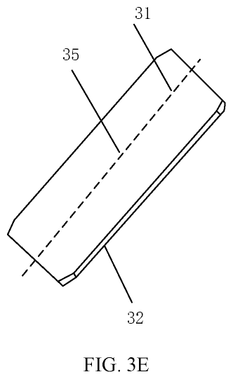

As shown in FIGS. 1 and 3B, the light path changing element 3 has an opening in the middle, and size of the opening is determined by the tilt angle of the reflector, spatial distribution of light source radiation field by, and the effective numerical aperture of the lens. As shown in FIG. 3A, 30 is an optical axis, 31 is a non-reflective surface of the reflector, 32 is a reflective surface of the reflector, 33 is an opening area in the middle, and 301 is a plane perpendicular to the optical axis. FIG. 3A is a projection of the light path changing element 3 on the 301 plane, and projection shape of the opening area 33 matches the shape of the light emission surface of the light source used, where sizes in two directions are related to the intensity characteristics of the light source radiation field.

In this example, the light path changing element is arranged obliquely to the optical axis, and the transmitting laser is emitted through the middle opening of the opening area 33. Wave signal of the reflected light is reflected by the reflective surface 32 to the detector to be received, and the reflected light is actually received by the detector for about 65% to 75%.

In some embodiments, the reflective surface of the light path changing element can also be coated with the antireflection film, which can be a dielectric film or a metal film, with a reflectivity greater than 90% and a waveband range of 880 nm˜950 nm. The non-reflective surface of the light path changing element can be treated to reduce reflectivity (to eliminate T0 influence caused by stray light), in which a corresponding area is coated with ink, black paint, glue, or another coating that reduces reflectivity, and can also be treated with an antireflection coating.

Second, the light path changing element 3 is set as an antireflection reflector, in which case the T0 influence of the stray light caused by an opening surface and the non-reflective surface can be reduced, and lens processing is simpler.

1. As shown in FIG. 3C, which is a projection of the light path changing element on the 301 plane, a first area 33 in the middle of the light path changing element is coated with the antireflection film without opening, and transmittance is greater than 80% (e.g., greater than 98%). The reflective surface 32 is coated with a high reflective film, with a reflectivity greater than 80% (e.g., greater than 90%), and a waveband range of 880 nm˜950 nm. Shape of a coating area 33 matches divergence condition of the light source used.

In this example, the light path changing element 3 is arranged obliquely to the optical axis, and the transmitting laser is emitted through the coating area 33. The reflected light is reflected by the reflective surface 32 to the detector to be received, and the reflected light is actually received by the detector for about 60% to 80%.

2. As an alternative implementation of this example, the light path changing element 3 has no opening, and the non-reflective surface 31 of the light path changing element is entirely coated with the antireflection film. FIG. 3D shows the reflective surface of the light path changing element, where the reflective surface 32 is coated with the high reflective film, and the first area 33 is coated with the antireflection film, with film reflectivity and waveband requirements unchanged. In this example, the light path changing element 3 is arranged obliquely to the optical axis, the transmitting laser is emitted through the coating area 33, and the reflected light is reflected by the reflective surface 32 to the detector to be received.

3. As another alternative implementation of this example, the light path changing element 3 has no opening, and the non-reflective surface 31 is entirely uncoated. FIG. 3D shows the non-reflective surface of the light path changing element, where the reflective surface 32 is coated with the high reflective film, and the first area 33 is coated with the antireflection film, with film reflectivity and waveband requirements unchanged. In this example, the light path changing element 3 is arranged obliquely to the optical axis, and the transmitting laser can be a polarized light source with a polarization greater than 95% (generally a semiconductor laser is linearly polarized light). According to Fresnel reflection law, polarization direction of the transmitting laser is parallel to a paper surface (P light), and at this time, more than 96% of the transmitting laser will be emitted through the coating area 33, and the reflected light will be reflected by the reflective surface 32 to the detector to be received.

4. As another alternative implementation of this example, the light path changing element 3 has no opening, and the non-reflective surface 31 is entirely uncoated. The reflective surface 32 is coated with the high reflective film, and the first area 33 is uncoated. FIG. 3D shows an emission surface of the light path changing element, in which the waveband and reflectivity requirements of the high reflective film are unchanged.

In this example, reflection of the transmitting laser by the non-reflective surface 31 can also be reduced using the Fresnel reflection principle. Specifically, the light path changing element is arranged obliquely to the optical axis, the transmitting laser can be a polarized light source with a polarization greater than 95% (generally a semiconductor laser is linearly polarized light), and the polarization direction of the transmitting laser is in P polarization state (P light). According to the Fresnel reflection law, the reflection of the transmitting laser by the uncoated area 33 is reduced, and the reflected light is reflected by the reflective surface 32 to the detector to be received. In some embodiments, a glass refractive index of the light path changing element 3 is greater than 1.72, and a corresponding Brewster angle is greater than 60 degrees.

Third, the light path changing element 3 is set as a polarizing lens, by which the stray light will be reduced a lot, and the structure of the polarizing lens is simple.

1. In some embodiments of the present disclosure, as shown in FIG. 3E, the light path changing element is a polarizing lens or a polarizer, and polarized light transmittance needs to be greater than 90%. The light path changing element 3 has no opening, polarization direction of the polarizing lens or polarizer is 35 (parallel to the paper surface P light), and the non-reflective surface and the reflective surface can be uncoated.

In this example, the light path changing element 3 is arranged obliquely to the optical axis, the transmitting laser can be a polarized light source with a polarization greater than 95% (generally a semiconductor laser is linearly polarized light), and the polarization direction of the transmitting laser is in P polarization state (P light). At this time, more than 90% of the transmitting laser will be emitted through the polarizing lens, and the reflected light will be reflected by the reflective surface 32 to the detector to be received. The reflected light is no longer polarized light, and the signal reflected by the polarizing lens has more than 45% of the reflected light.

2. As another alternative implementation of this example, the light path changing element 3 is a light-transmitting material, such as ordinary glass, and a middle area 33 is coated with a polarizing film (without opening), so that light with the same polarization direction as the transmitting laser has a high transmittance. The non-reflective surface 31 is uncoated, and the reflective surface 32 is coated with the high reflective film, with film reflectivity and waveband requirements unchanged.

In this example, the light path changing element 3 is arranged obliquely to the optical axis, and the tilt angle needs to be close to a polarization angle of the light path changing element. The transmitting laser can be a polarized light source with a polarization greater than 95% (generally a semiconductor laser is linearly polarized light), and the polarization direction of the transmitting laser is the same as the polarization direction 35 of the polarizing film. At this time, more than 90% of the transmitting laser will be emitted through the polarizing lens, and the reflected light will be reflected by the reflective surface 32 to the detector to be received. Because target characteristics are uncertain, the reflected light is no longer polarized light, and some of the reflected light can still be reflected to the detector through the area 33, so that detected echo power can be increased. At this time, the reflected light reflected by the reflective surface 32 can be controlled to be above 65%.

Fourth, the light path changing element 3 is set as a polarizing lens and a non-reciprocal polarization rotation device (Faraday rotator or ¼ piece). With this configuration, the stray light can be reduced a lot, and received signal strength can be increased a lot. However, number of lenses and cost increase, and structure becomes complicated.

Specifically, in this example, both the first area and the second area include the light-transmitting substrates coated with the polarizing film, and the polarization direction of the polarizing film is the same as the polarization direction of the emitted light pulse. Also, a non-reciprocal polarization rotation device is arranged on one side of the transceiver, so that the polarization direction of the light pulse is perpendicular to the polarization direction of the reflected light passing through the non-reciprocal polarization rotation device.

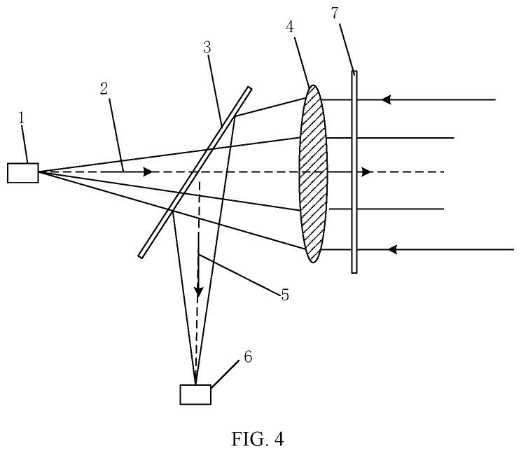

As shown in FIG. 4, laser radiated light is linearly polarized light, and the light path changing element is the polarizing lens or the polarizer. Polarization transmission direction is the same as polarization direction of the laser radiated light, and the polarized light transmittance needs to be greater than 80%. The light path changing element 3 has no opening, and has a higher reflectivity for the light in a vertical polarization direction, which is greater than 80%. The non-reflective surface and the reflective surface can be uncoated. A Faraday rotator 7 is arranged behind the collimation lens, in which the corresponding wavelength is 905 nm, and the aperture is not less than lens aperture. The Faraday rotator is configured to align the polarization direction of the light pulse emitted by the light source after collimation and the polarization direction of the emitted light pulse to be at 45 degrees. When the transmitting laser is reflected by an external standard lens, due to the Faraday rotator, the polarization direction of the reflected light after passing through the Faraday rotator is perpendicular to the polarization direction of the transmitting laser, so that the reflected light can be reflected by the reflector to the detector to be detected.

In this example, the transmitting laser can be a polarized light source with a polarization greater than 95%, and the polarization direction of the transmitting laser is the same as the polarization transmission direction of the light path changing element 3. The emitted laser passing through the polarizer is polarized light, which is irradiated on an object, reflected by the object, and received by the radar. After the light passes through the Faraday rotator, its polarization direction is perpendicular to the polarization direction of the emitted light, and is reflected by the reflector to the detector for detection. The stray light in environment is generally non-polarized light, and the reflector only has a high reflectivity for light polarized in a particular direction, thus, it is helpful to reduce the stray light in the environment detected by the detector, thereby improving signal-to-noise ratio of the system.

In the embodiments of the present disclosure described above, the light source can be an edge-emitting laser. The detector includes an avalanche diode configured to receive at least part of the reflected light converged by the transceiver, and convert the received reflected light into an electrical signal.

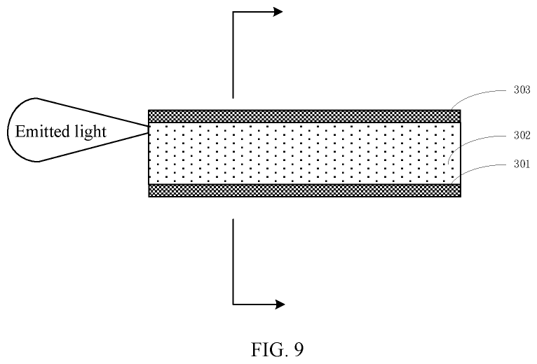

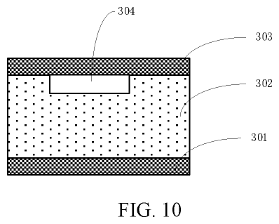

Structure of the EEL laser is shown in FIGS. 9 and 10. The EEL laser includes a first electrode 301 and second electrode 303, where a first heat sink is provided on a first surface of a laser diode chip 302 where the first electrode is located, and a second heat sink is provided on a second surface of the laser diode chip where the second electrode is located. In some embodiments, the laser diode chip has a cuboid structure, and the first surface and the second surface are upper and lower surfaces of the cuboid structure. An emission surface of the laser diode chip refers to a side surface of one end of the cuboid structure, as shown in FIG. 9, the emission surface of the laser diode chip is a side surface of left end of the cuboid structure, and a light emitting area 304 is arranged under the second electrode, as shown in FIG. 10.

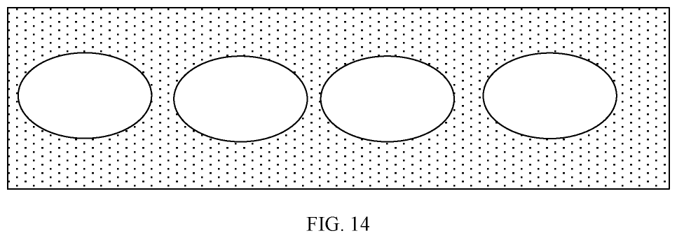

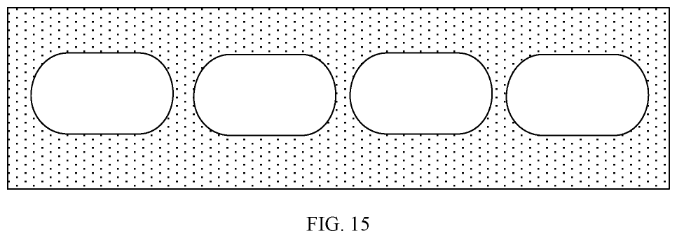

The light source includes an edge-emitting laser, or the light source includes an edge-emitting laser array including a plurality of edge-emitting lasers, such as an edge-emitting laser array having several rows and several columns. Similarly, the detector is an avalanche diode array corresponding to the light source, as shown in FIGS. 14 and 15, such as an avalanche diode array having several rows and several columns. Each laser corresponds to each detector in a one-to-one manner, and each detector is configured to receive the reflected light of the light beam emitted by the laser corresponding thereto.

In the embodiments of the present disclosure, photosensitive surface of the APD is optimized to match the shape of the light spot of the reflected light. Under the premise of ensuring that the reflected light is mostly received, the received ambient light is reduced, so as to increase signal-to-noise ratio of the ranging device and the measurement range of the system. In the ranging device using EEL as the light source, the photosensitive surface of the APD is optimally designed to be elliptical or similar to elliptical.

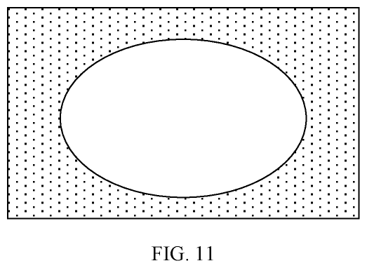

For example, the photosensitive surface of the APD is elliptical, as shown in FIG. 11, where ellipse can be flexibly adjusted according to ellipticity of the light pulse emitted by the light source, as long as the shape of the light pulse emitted by the light source is similar to the shape of the photosensitive surface of the APD.

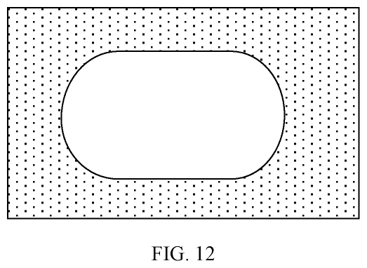

In addition to the elliptical shape, the photosensitive surface of the APD can also be other shapes, such as similar to a rectangle or similar to an ellipse, in which four corners of a rectangle are rounded, as shown in FIG. 12, which are more rounded relative to sharp corners.

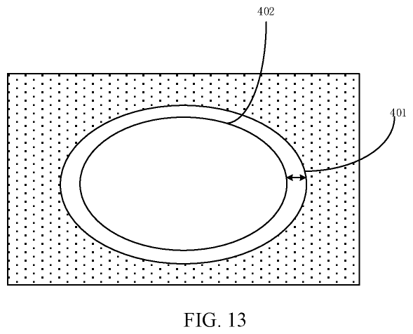

The shape of the photosensitive surface of the avalanche diode matches the shape of the light spot of the reflected light. For example, as shown in FIG. 13, size of photosensitive surface 401 of the avalanche diode is larger than size of the light spot of reflected light 402, and difference between the two sizes is equal to or greater than an assembly error, as shown by arrow, so as to ensure that the light spot of the reflected light falls within the photosensitive surface of the APD. In actual installation and debugging process, the assembly error can be reserved between the avalanche diode and the EEL.

By optimizing the APD in the detector, the photosensitive surface of the APD can be better matched with the reflected light spot, so that ambient light noise and electrical noise are reduced, and signal-to-noise characteristics and ranging performance of the system are optimized. Using a smaller APD can achieve better system performance, which also helps to reduce APD device cost.

The present disclosure provides a ranging device, in which a LIDAR coaxial transceiver lens structure and a pulse laser TOF principle/frequency shift measurement/phase shift measurement are used, and can be applied to radar and range detection field in combination with a beam scanning system.

Transceiver system in the ranging device of the present disclosure has the advantages of stronger received signal, large system tolerance, simple assembly, and low cost. Selected materials are easy to obtain, and processing scheme is mature, which can be applied in batch engineering and is particularly suitable for some large-aperture transceiver systems.

The technical terms used in the embodiments of the present disclosure are only used to describe specific embodiments and are not intended to limit the present disclosure. As used herein, the singular forms “a,” “an,” and “the” are used to include the plural forms as well, unless the context clearly indicates otherwise. Further, the terms “include” and/or “including” used in the specification refer to the presence of the described features, integers, steps, operations, elements, and/or components, but do not exclude the presence or addition of one or more other features, integers, steps, operations, elements, and/or components.

The corresponding structures, materials, actions, and equivalents (if any) of all devices or steps and functional elements in the appended claims are intended to include any structure, material, or action for performing the function in combination with other explicitly claimed elements. The description of the present disclosure is presented for the purpose of examples and description, but is not intended to be exhaustive or to limit the present disclosure to the disclosed form. Various modifications and variations will be apparent to those skilled in the art without departing from the scope and spirit of the present disclosure. The embodiments described in the present disclosure can better disclose the principles and practical applications of the present disclosure, and enable those skilled in the art to understand the present disclosure.

The flow chart described in the present disclosure is only an embodiment, and various modifications and changes can be made to the chart or the steps in the present disclosure without departing from the spirit of the present disclosure. For example, these steps can be performed in a different order, or some steps can be added, deleted, or modified. Those skill in the art can understand that implementing of all or part of the processes of the embodiments described above and equivalent changes made in accordance with the claims of the present disclosure still fall within the scope of the present disclosure.

What is claimed is:

1. A ranging device comprising:
a light source configured to emit a light pulse;
a transceiver configured to collimate the light pulse and converge at least part of reflected light of the light pulse reflected by a detection object;
a detector arranged on the same side of the transceiver as the light source, and configured to receive the at least part of the reflected light converged by the transceiver and convert the at least part of the reflected light into an electrical signal for measuring a distance between the detection object and the ranging device; and
a light path changing element arranged on the same side of the transceiver as the light source and the detector, and configured to combine emission light path of the light pulse and reception light path of the detector;
wherein the light path changing element includes an area configured to transmit or reflect part of the light pulse from the light source to the transceiver, a reception solid angle of the area with respect to the light pulse being 20%-40% of a reception solid angle of the detector with respect to the reflected light.

2. The ranging device of claim 1, wherein a numerical aperture of the transceiver is 0.15-0.5.

3. The ranging device of claim 1, wherein:
the area is a first area;
the light path changing element further includes a second area; and
the first area is configured to transmit the part of the light pulse from the light source to the transceiver and the second area is configured to reflect part of the reflected light converged by the transceiver to the detector; or the first area is configured to reflect the part of the light pulse from the light source to the transceiver, and the second area is configured to transmit the part of the reflected light converged by the transceiver to the detector.

4. The ranging device of claim 3, wherein a projected area of the first area on a plane perpendicular to an optical axis of the light pulse is 20%-40% of a projected area of the second area on the plane.

5. The ranging device of claim 1, wherein the light path changing element is configured to emit 60%-85% of a total energy of the light pulse emitted by the light source to the transceiver.

6. The ranging device of claim 1, wherein an energy of the reflected light received by the detector accounts for more than 60% of an energy of the reflected light received by the light path changing element.

7. The ranging device of claim 1, wherein:
the reception solid angle of the area with respect to the light pulse is a ratio of a projected area of the first area on a plane perpendicular to an optical axis of the light pulse to a square of a distance between the plane and the light source; and/or
an effective reception solid angle of the detector with respect to the reflected light is less than or equal to a difference between the reception solid angle of the detector with respect to the reflected light and the reception solid angle of the area with respect to the light pulse.

8. The ranging device of claim 1, wherein:
a shape of a projection of the area on a plane perpendicular to an optical axis of the light pulse matches a shape of a light spot of the light pulse formed on the plane; or
a shape of the area matches a shape of light emission surface of the light source.

9. The ranging device of claim 8, wherein:
the shape of the projection of the area on the plane perpendicular to the optical axis of the light pulse is circular, elliptical, trapezoidal, or rectangular that matches the shape of the light spot of the light pulse formed on the plane; or
the shape of the area is circular, elliptical, trapezoidal, or rectangular that matches the shape of the light spot.

10. The ranging device of claim 1, wherein the light source includes a laser diode, an aperture of the area in a fast axis direction of the laser diode being larger than an aperture of the area in a slow axis direction of the laser diode.

11. The ranging device of claim 1, wherein the area includes a first end and a second end located at two sides of an optical axis of the light pulse, the first end being closer to the light source than the second end, and an aperture of the second end being larger than an aperture of the first end in a direction parallel to the optical axis of the light pulse.

12. The ranging device of claim 11, wherein the area is trapezoidal.

13. The ranging device of claim 1, wherein a projected area of the area on a plane perpendicular to an optical axis of the light pulse is smaller than a light spot area of the light pulse formed on the plane.

14. The ranging device of claim 1, wherein a central axis of the light source is perpendicular to a central axis of the detector.

15. The ranging device of claim 1, wherein the light source is one of a plurality of light sources of the ranging device, the detector is one of a plurality of detectors of the ranging device that correspond to the plurality of the light sources, and the light path changing element is one of a plurality of light path changing elements of the ranging device that correspond to the plurality of light sources and the plurality of detectors.

16. The ranging device of claim 1, wherein the light source includes at least an edge-emitting laser, and the detector includes at least an avalanche diode.

17. The ranging device of claim 16, wherein a shape of a photosensitive surface of the avalanche diode matches a shape of a light spot of the reflected light.

18. The ranging device of claim 16, wherein a size of a photosensitive surface of the avalanche diode is larger than a size of a light spot of the reflected light, a difference between the size of the photosensitive surface and the size of the light spot being equal to or greater than an assembly error.

19. The ranging device of claim 16, wherein a shape of a photosensitive surface of the avalanche diode is rectangular, elliptical, or similar to elliptical.

20. The ranging device of claim 19, wherein a shape similar to elliptical is a rectangle with rounded corners.

21. The ranging device of claim 16, wherein:
the light source includes an edge-emitting laser line array formed by a plurality of edge-emitting lasers regularly arranged, and the detector includes an avalanche diode line array formed by a plurality of avalanche diodes regularly arranged; and
the edge-emitting lasers in the edge-emitting laser line array correspond to the avalanche diodes in the avalanche diode line array in a one-to-one manner.

22. The ranging device of claim 16, wherein:
the light source includes an edge-emitting laser area array formed by a plurality of edge-emitting lasers regularly arranged, and the detector includes an avalanche diode area array formed by a plurality of avalanche diodes regularly arranged; and
the edge-emitting lasers in the edge-emitting laser area array correspond to the avalanche diodes in the avalanche diode area array in a one-to-one manner.
